(19) United States
(12) Patent Application Publication
(10) Pub. No.: US 2008/0123264 A1
(43) Pub. Date: May 29, 2008

(54) Surgical machine with stowable display

(76) Inventors: Laszlo O. Romoda, San Clemente, CA (US); Christopher Horvath, Irvine, CA (US); Merlin Hall, Keller, TX (US)

Correspondence Address: ALCON, IP LEGAL, TB4-8, 6201 SOUTH FREEWAY, FORT WORTH, TX, 76134, US

(21) Appl. No.: 11/511,974

(22) Filed: Aug. 29, 2006

(51) Int. Cl. H05K 5/00

(52) U.S. Cl. 361/681

(57) ABSTRACT

A surgical machine has a surgical console, a display, and a cover. The surgical console has a cavity that receives the display. The display is connected to the surgical console and communicates with it. The cover is connected to the console and protects the display when the display is stowed in the cavity of the surgical console. The surgical machine is portable when the display is stowed in the cavity of the surgical console.

### FIELD OF THE INVENTION

The present invention relates to surgical machines and more particularly to a surgical machine with a stowable display that allows for ease of transport.

### BACKGROUND OF THE INVENTION

Most ophthalmic surgeries performed today involve the use of surgical equipment. For example in cataract removal, a machine is typically employed to remove the old lens by a process called phacoemulsification. In phacoemulsification, the old lens is eroded by a hand piece and aspirated out of the eye. The hand piece acts to disintegrate the lens, deliver fluid into the eye, and aspirate the fluid and lens particles. The hand piece is connected to a console that provides the necessary power, fluid flow, and vacuum. Similar machines exist for laser eye surgery, vitroretinal surgery, and other types of ophthalmic procedures.

Most electronic surgical machines have a user interface that allows the doctor to control the machine. These user interfaces may incorporate the latest in touch screen display technology. Using a touch screen display allows the doctor to receive information about how the machine is performing. A touch screen display can also receive instructions from the doctor in an easy and straightforward fashion. The user interface provided by a touch screen display can be intuitive and robust, providing the doctor with an effective way to perform surgery.

More particularly, ophthalmic surgery often involves complex surgical equipment in the form of a console with associated work pieces. This equipment is usually computer controlled and very sophisticated. A touch screen display is often employed to provide the doctor with important information about how the equipment functions. This same touch screen display may also receive input from the doctor to control the equipment during surgery.

This surgical equipment typically contains both mechanical and electronic components. As technology advances, these components become more compact and powerful. Accordingly, the size of a typical piece of surgical equipment has decreased over the years. As the size decreases, the portability of such a device increases. This portability means that the device can be more fully utilized. It can be taken to different operating rooms or even transported overseas to treat patients in developing countries. Despite the advances in technology that lead to a decreased size of these devices, a need continues to exist for a surgical machine that is easily portable.

### SUMMARY OF THE INVENTION

In one embodiment consistent with the principles of the present invention, the present invention is a surgical machine with a surgical console and a display. The surgical console has a cavity. The display is in communication with the surgical console. The display is stowable in the cavity of the surgical console so that the surgical machine is portable.

In another embodiment consistent with the principles of the present invention, the present invention is a surgical machine having a surgical console, a display, and a cover. The surgical console has a cavity that receives the display. The display is connected to the surgical console and communicates with it. The cover is connected to the console and protects the display when the display is stowed in the cavity of the surgical console. The surgical machine is portable when the display is stowed in the cavity of the surgical console.

In another embodiment consistent with the principles of the present invention, the present invention is a surgical machine with a surgical console, a low-profile, touch screen display, and a cover. The surgical console has a cavity that receives the display. The low-profile, touch screen display is connected to the console via a first hinge and communicates with the console. The cover is connected to the console via a second hinge. The cover protects the low-profile, touch screen display when the display is stowed in the cavity of the surgical console. The surgical machine is portable when the low-profile, touch screen display is stowed in the cavity of the surgical console.

It is to be understood that both the foregoing general description and the following detailed description are exemplary and explanatory only and are intended to provide further explanation of the invention as claimed. The following description, as well as the practice of the invention, set forth and suggest additional advantages and purposes of the invention.

### BRIEF DESCRIPTION OF THE DRAWINGS

The accompanying drawings, which are incorporated in and constitute a part of this specification, illustrate the embodiments of the invention and together with the description, serve to explain the principles of the invention.

FIG. 1 is a perspective view of a surgical machine with a stowable display according to an embodiment of the present invention.

FIG. 2 is a perspective view of a surgical machine with a stowable display according to an embodiment of the present invention.

### DETAILED DESCRIPTION OF THE PREFERRED EMBODIMENTS

Reference is now made in detail to the exemplary embodiments of the invention, examples of which are illustrated in the accompanying drawings. Wherever possible, the same reference numbers are used throughout the drawings to refer to the same or like parts.

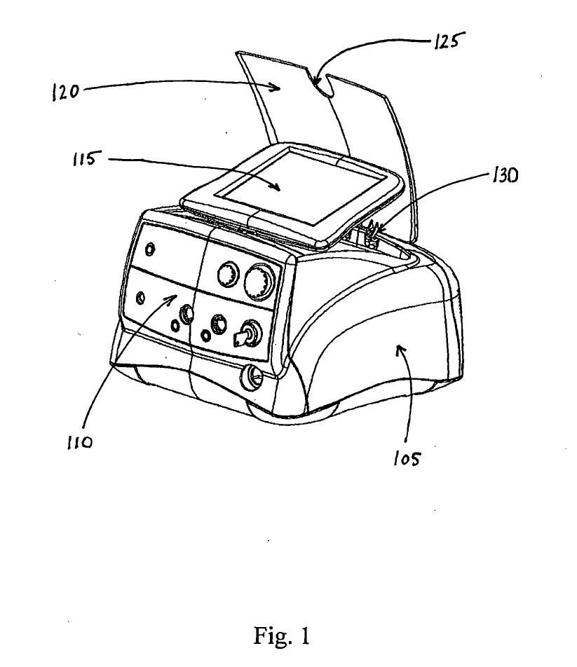

FIG. 1 is a perspective view of a surgical machine with a stowable display according to an embodiment of the present invention. The surgical machine comprises a surgical console 105, a display 115, and a cover 120. The console 105 has a front panel 110. The cover 120 has a notch 125. The cover 120 is connected to the surgical console 105 by hinge 130.

Surgical console 105 typically includes a computer, control circuitry, and other mechanical devices (not shown) used to perform a procedure. Peripherals, such as operating hand pieces, may be connected to the front panel 110 of surgical console 105. Power is provided to these peripherals by surgical console 105. Additionally, surgical console 105 controls the operation of these peripherals. Surgical console may also have a handle (not shown) to facilitate easy transport of the surgical machine.

Surgical console 105 has a cavity for receiving display 115. In FIG. 1, the cavity is shown on a top surface of surgical console 105. The cavity is sized to fit display 115. In addition, the cavity may also have latches, stops, protrusions, or other similar structures to secure display 115 in the cavity. These structures serve to protect display 115.

Display 115 conveys information about the surgical machine to a medical professional. For example, in ophthalmic surgery, display 115 may display information about the operation of a cataract or retinal surgery machine. Display 115 typically shows functional parameters such as temperature or fluid pressure. Display 115 might also show various steps that are performed during an ophthalmic procedure.

In one embodiment of the present invention, display 115 is a touch screen display. Touch screen displays allow a user to input a command by touching the screen of the display. For example, a doctor can start a procedure by touching a “start” icon displayed on the screen of the display 115. In this manner, the display 115 receives a control input (that the doctor wishes to start the procedure) by sensing the pressure of the doctor's finger on the screen of the display 115. The surgical machine can then respond to the control input.

In other embodiments of the present invention, display 115 is a liquid crystal display (LCD), plasma display, or other flat panel display. In this case, display 115 may provide information to the doctor about the function of the surgical machine or the status of the operation itself. For example, display 115 may display information about the completion of a certain step in the operation.

Cover 120 is connected to surgical console 105 with one or more hinges, such as hinge 130. Cover 120 has an optional notch 125. Notch 125 allows a person to open cover 120 when it is in its closed position. Cover 120 may also have a latching mechanism (not shown) to secure cover 120 to surgical console 105. In this manner, cover 120 is held in place when closed thus protecting display 115. Cover 120, like the housing of surgical console 105, may be made of a polymer or other suitable material.

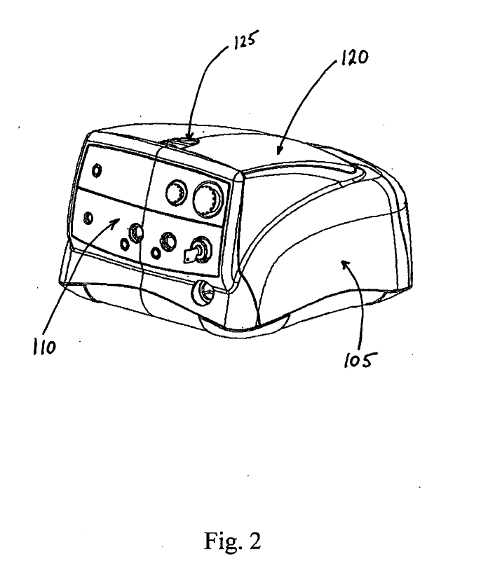

FIG. 2 is a perspective view of a surgical machine with a stowable display according to an embodiment of the present invention. In FIG. 2, display 115 is stowed in surgical console 105. In this position, cover 120 protects display 115. A person may open cover 120 by pulling on notch 125. Stowing the display 115 as shown in FIG. 2 also allows for ease of transport. The surgical machine can be carried like a small suitcase with an optional handle (not shown) located on surgical console 105. Alternatively, the surgical machine can be put in a box or suitcase to be transported. The surgical machine may also fit under an airline passenger seat or other confined location. This configuration also allows for easy shipment as the display 115 is protected during shipping by cover 120.

An easily transportable or shippable surgical machine has many benefits. A doctor can use a single machine at different locations or different operating rooms. Some ophthalmic surgeons cover geographic areas with different offices. A surgeon may spend one day every few weeks at a rural hospital. The expense associated with dedicating a surgical machine to a rural hospital cannot be justified. In such a case, a portable surgical machine is the only economically feasible way to provide surgical services to people at the rural hospital.

In other cases, a portable surgical machine can be brought to disaster areas, emergency sites, developing countries, or military field hospitals. In each of these locations, a surgical machine may provide necessary treatment to people who otherwise could not be helped. By bringing the operating room to the site, valuable time is saved in treating patients.

From the above, it may be appreciated that the present invention provides an improved surgical machine that is more easily portable. The present invention allows a medical professional to conveniently transport a surgical machine. The present invention is illustrated herein by example, and various modifications may be made by a person of ordinary skill in the art.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A surgical machine comprising:
a surgical console having a cavity; and
a display in communication with the surgical console;
wherein the display is stowable in the cavity of the surgical console so that the surgical machine is portable.

2. The surgical machine of claim 1 further comprising a hinge connecting the display to the surgical console.

3. The surgical machine of claim 1 further comprising a cover connected to the console, the cover for protecting the display when the displayed is stowed in the cavity of the surgical console.

4. The surgical machine of claim 3 further comprising a hinge connecting the cover to the surgical console.

5. The surgical machine of claim 1 wherein the display is a flat panel display.

6. The surgical machine of claim 1 wherein the display is a touch screen display.

7. The surgical machine of claim 1 wherein when the display is stowed in the cavity of the surgical console, the surgical machine fits under an airline passenger seat.

8. The surgical machine of claim 1 further comprising a handle located on the surgical console.

9. A surgical machine comprising:
a surgical console having a cavity therein;
a display connected to the console, the display in communication with the console; and
a cover connected to the console, the cover for protecting the display when the display is stowed in the cavity of the surgical console;
wherein the surgical machine is portable when the display is stowed in the cavity of the surgical console.

10. The surgical machine of claim 9 further comprising a hinge connecting the display to the surgical console.

11. The surgical machine of claim 9 further comprising a hinge connecting the cover to the surgical console.

12. The surgical machine of claim 9 wherein the display is a flat panel display.

13. The surgical machine of claim 9 wherein the display is a touch screen display.

14. The surgical machine of claim 9 further comprising a handle located on the surgical console.

15. A surgical machine comprising:
a surgical console having a cavity therein;
a low-profile, touch screen display connected to the console via a first hinge, the low-profile, touch screen display in communication with the console;
a cover connected to the console via a second hinge, the cover for protecting the low-profile, touch screen display when the display is stowed in the cavity of the surgical console;
wherein the surgical machine is portable when the low-profile, touch screen display is stowed in the cavity of the surgical console.

16. The surgical machine of claim 15 further comprising a handle located on the surgical console.
